(19) United States
(12) Patent Application Publication
(10) Pub. No.: US 2009/0223561 A1
(43) Pub. Date: Sep. 10, 2009

(54) METHOD OF ETCHING ASYMMETRIC WAFER, SOLAR CELL INCLUDING THE ASYMMETRICALLY ETCHED WAFER, AND METHOD OF MANUFACTURING THE SAME

(75) Inventors: Jong-Dae KIM, Seoul (KR); Bum-Sung Kim, Seoul (KR); Ju-Hwan Yun, Seoul (KR); Young-Hyun Lee, Seoul (KR)

Correspondence Address: BIRCH STEWART KOLASCH & BIRCH, PO BOX 747, FALLS CHURCH, VA, 22040-0747, US

(73) Assignee: LG Electronics Inc., Seoul (KR)

(21) Appl. No.: 12/388,913

(22) Filed: Feb. 19, 2009

(30) Foreign Application Priority Data
Feb. 19, 2008 (KR) 10-2008-0014903

(51) Int. Cl. H01L 31/0236; H01L 21/306; H01L 31/18

(52) U.S. Cl. 136/256; 438/745; 438/706; 438/704; 438/57; 257/E21.215

(57) ABSTRACT

With the present invention, two wafers for a solar cell only whose light receiving surfaces are selectively etched can be simultaneously obtained by overlapping the two wafers and performing a single-sided etching or an asymmetric etching thereon. The present invention provides a method of etching a wafer comprising: performing a single-sided etching or an asymmetric etching on the wafer, wherein the performing the single-sided etching or the asymmetric etching comprises: overlapping two wafers whose one sides face each other; and etching the overlapped two wafers, and a solar cell including the etched wafers.

This application claims priority to Korean Patent Application No. 10-2008-0014903, filed on Feb. 19, 2008, in the Korean Intellectual Property Office, the entire contents of which are hereby incorporated by reference.

### BACKGROUND OF THE INVENTION

1. Field of the Invention

The present invention relates to a method of etching an asymmetric wafer, a solar cell including the asymmetrically etched wafer, and a method of manufacturing the same. More particularly, the present invention relates to a method of etching an asymmetric wafer in which two wafers for a solar cell whose light receiving surfaces are selectively etched can be simultaneously obtained by overlapping the two wafers and performing a single-sided etching or an asymmetric etching thereon, a solar cell including the asymmetrically etched wafer, and a method of manufacturing the same.

2. Description of the Related Art

Owing to problems of environmental pollution and an exhaustion of resources, etc., there is an urgent demand for the development of pollution free clean energy. Therefore, a solar cell has attracted a great deal of interest, together with nuclear energy and wind power. A solar cell based on a silicon (Si) single crystal and polycrystalline substrate has currently developed and commercialized, and studies into an amorphous silicon thin film solar cell and a thin film type compound semiconductor solar cell have been actively progressed in order to manufacture a cheaper solar cell through reduction in use of raw materials.

A solar cell, which is a device that converts light energy into electric energy using a photovoltaic effect, has a junction form of a p-type semiconductor and an n-type semiconductor and generates current by movement of electrons or holes generated by solar light to the side opposite from which they were formed, thereby generating electricity.

Such a solar cell is classified into a silicon solar cell, a thin film solar cell, a dye-sensitized solar cell, an organic polymer solar sell, and the like according to constituent materials. Such a solar cell is independently used as a main power supply for an electronic clock, a radio, an unmanned lighthouse, an artificial satellite, a rocket, and the like and as an auxiliary power supply by being connected to a commercial alternating power supply.

Recently, there is much growing interest into solar cells due to an increased need of alternate energy.

In the solar cell, it is important to increase conversion efficiency associated with the proportion of incident sunlight that is converted into electric energy.

Various studies have been made so as to increase the conversion efficiency.

### SUMMARY OF THE INVENTION

An object of the present invention is to provide a method of etching a wafer in which as a plurality of wafers are overlapped and etched, the plurality of wafers that can be applied to a solar cell can be simultaneously obtained, having a single-sided etching structure or an asymmetric etching structure.

Another object of the present invention is to provide a method of etching a wafer in which as a plurality of wafers are overlapped and etched, an unnecessary backside etching can be removed by selectively etching them.

Yet another object of the present invention is to provide a solar cell that uses an etched side obtained by performing a single-sided etching or a double-sided asymmetric etching simultaneously on a plurality of wafers as a light receiving surface, and a method of manufacturing the same.

### TECHNICAL SOLUTION

To achieve the above objects, according to one aspect of the present invention, there is provided a method of etching a wafer comprising: selectively etching only a single side of the wafer, and asymmetrically etching both sides of the wafer with different etching rates.

The etching only the single side of the wafer comprises closely adhering sides of the two wafers that face each other having no gap, simultaneously etching sides of the closely adhered wafers, exposed to the external, and separating the closely adhered wafers.

The asymmetrically etching both sides of the wafer comprises overlapping a plurality of wafers so as to have predetermined gaps between the respective wafers, etching the overlapped wafers, and separating the overlapped wafers.

In one embodiment of the present invention, the etching rate refers to rate or degree to be etched. Therefore, if an etching performance time, an etching method, a difference in etching solution, and an etching performance position, etc. are different, a wafer surface roughness becomes different, thereby causing a difference in etching rate for both sides of the wafer.

The etching performance time and the etching method are not particularly limited. In an etching method using etching solution, a method of differing the composition of the etching solution may be included. An uneven etching is induced by differing the position of wafer where the etching is performed, making it possible to manufacture a wafer having both sides asymmetrically etched.

In one embodiment of the present invention, the gaps between the respective wafers, into which etching solution can be infiltrated, may have different widths.

The spaced distance between the gaps is not limited, but it may be sufficient to satisfy the distance that the inner sides of the separated wafers can be etched by the etching solution infiltrated into the gaps.

When etching is performed having the gaps between the plurality of wafers, the degree that the etching solution is infiltrated into the wafer sides which are symmetrical to the wafer sides of the lateral-most sides, having gaps therebetween, is changed, making it possible to etch the respective wafer sides asymmetrically.

The plurality of wafers may be overlapped with each other and be etched, having corresponded central lines or having overlapped portions, wherein this may be a method of etching the wafer asymmetrically.

According to one embodiment of the present invention, the respective steps are performed continuously or discontinuously.

The continuous performance of the respective steps means that a series of work processes are continuously performed, and the discontinuous performance thereof means that each step is not continuously performed and other process can be added any time.

According to one embodiment of the present invention, although the etching of the wafer may be performed using any one of a wet etching, a dry etching or a combined wet-dry etching, the present invention is not particularly limited thereto and it may be sufficient if any well-known etching technique that can be easily comprehended by those skilled in the art is applied to the present invention.

To achieve the above objects, according to another aspect of the present invention, there is provided a solar cell, which is a bulk silicon solar cell that includes a silicon substrate that has a light receiving surface and a non-light receiving surface, the light receiving surface and the non-light receiving surface having unevenness in different shapes.

The unevenness formed on the light receiving surface is different from that on the non-light receiving surface in view of one or more of the number, size, height, and shape thereof.

The number of unevenness may mean the frequency that the unevenness is shown or the number that the unevenness is counted centering on the convex portion of the unevenness.

The size of the unevenness may mean the outer surface area of the convex portion of the unevenness or the area of a base surface occupied by the convex portion of the unevenness.

The height of the unevenness may mean the distance between the highest portion and the base surface of the convex portion of the unevenness.

The shape of the unevenness may mean the external appearance between the plurality of unevenness, wherein the shape of thereof may be regular or irregular.

The number of the unevenness formed on the light receiving surface may be greater than that of formed on the non-light receiving surface. In other words, the density of the unevenness on the light receiving surface may be higher than that on the non-light receiving surface.

Also, according to another embodiment of the present invention, the unevenness may be formed on the light receiving surface but the unevenness may not be formed on the non-light receiving surface.

Meanwhile, the reflectivity of the light receiving surface of the silicon substrate may be lower than that of the non-light receiving surface thereof. Therefore, the rate that light incident on the light receiving surface is reflected again on the outer surface to be lost is low, making it possible to provide a solar cell having an excellent light trapping effect.

Therefore, the solar cell according to one embodiment of the present invention has an entire structure where centering on the silicon substrate that includes the light receiving surface and the non-light receiving surface, an emitter doped with a semiconductor impurity, an anti-reflection layer, and a front surface electrode are formed sequentially on the light receiving surface of the substrate, and a back surface field (BSF) layer and a back surface electrode are formed sequentially on the non-light receiving surface of the substrate.

The emitter is a semiconductor layer doped with a conductive impurity other than a semiconductor impurity type doped on the silicon substrate. Therefore, an interface between the emitter and the silicon substrate that are doped with different conductive semiconductor impurities forms a pn junction to be separated to pairs of electrons and holes by solar light, thereby generating carriers.

The anti-reflection layer, which has a light trapping function that prevents incident light from being reflected again and emitted to the external, may be made of silicon nitride (SiN) and silicon oxide (SiO₂), etc.

The front surface electrode is made of a metallic element such as silver (Ag), etc., wherein a predetermined portion thereof is contacted to the emitter. The front surface electrode forms a potential difference by pulling the carriers separated from the pn junction surface that is the interface between the emitter and the silicon substrate.

The back surface field layer formed on the non-light emitting surface, which is a semiconductor layer doped with the same conductive impurity as the semiconductor impurity type doped on the silicon substrate, provides a back surface field effect to the solar cell.

In some cases, a transparent electrode layer that enhances anti-reflection and conductivity may further be provided on the emitter and the back surface field layer.

The transparent electrode layer may be made of indium tin oxide (ITO) or aluminum-doped zinc oxide (AZO), etc.

As to the anti-reflection layer, the front surface electrode, the BSF layer, and the back surface electrode of the solar cell according to one embodiment of the present invention, the material or raw material and the formation method, etc., thereof may be constituted by those skilled in the art from well-known techniques so that the detailed technique thereof will be omitted.

In the solar cell according to one embodiment of the present invention, the etching is performed, so that the surfaces of the light receiving surface and the non-light receiving surface have different unevenness, by differing an etching performance time, an etching performance position, or an etching method.

According to yet another aspect of the present invention, there is provided a method of manufacturing a bulk silicon solar cell, comprising etching only a single side of a silicon substrate selectively or etching both sides of the silicon substrate asymmetrically with different etching rates.

Generally, a method of manufacturing a bulk silicon solar cell comprises preparing a silicon substrate, forming an emitter, an anti-reflection layer, and a front surface electrode sequentially on a light emitting surface of the silicon substrate, and forming a back surface field layer and a back surface electrode sequentially on a surface opposite to the light emitting surface of the silicon substrate. According to one embodiment of the present invention, it is characterized in that the asymmetric uneven surface is formed by performing an etching on any one of the light emitting surface and the non-light emitting surface of the silicon substrate or by performing an etching differently on both surfaces thereof.

The bulk silicon solar cell as described above can manufacture and provide the wafer used in the silicon substrate to have economically high yields, making it possible to reduce entire manufacturing costs of the solar cell.

The silicon wafer substrate included in the solar cell according to one embodiment of the present invention is characterized in that a side of a plurality of wafers completely overlapped, exposed to the external, is etched to etch a sectional side, or portions or an entirety thereof are overlapped having gaps between the respective wafers and are etched to etch the both sides of the wafer in different shapes.

The shape to be etched is not particularly limited but may be implemented to have various etching side shapes that can be easily applied by those skilled in the art from well-known techniques.

The shape of the unevenness on the etched light receiving surface or the non-light emitting surface maybe formed as a pyramid shape, a circular cylinder shape, and a multilateral column shape, wherein the unevenness may have a regular arrangement or an irregular arrangement.

The base surface of the unevenness may have a shape that is flat or concavely dug.

If the plurality of wafers are overlapped in portions rather than are completely overlapped, centering on the central point, to be etched, the unevenness will be formed on the portion exposed to the etching solution.

With the present invention as described above, two wafers are overlapped and the etching is performed thereon, making it possible to simultaneously obtain two wafers for a solar cell that have a single-sided etching structure or an asymmetric etching structure, and unnecessary wafer back surface etching can be removed by selectively etching only the light receiving surface, making it possible to simplify work manpower and to reduce manufacturing costs.

### BRIEF DESCRIPTION OF THE DRAWINGS

These and other objects, features, aspects, and advantages of the present invention will be more fully described in the following detailed description of preferred embodiments and examples, taken in conjunction with the accompanying drawings. In the drawings:

FIGS. 1 to 3 are process views explaining a method of etching a wafer according to an embodiment of the present invention;

FIG. 4 is a view explaining a method of performing a single-sided etching on a wafer according to an embodiment of the present invention;

FIG. 5 is a view explaining a method of performing an asymmetric etching on a wafer according to an embodiment of the present invention;

FIG. 6 is a view explaining a method of etching a wafer according to the present invention using a discontinuous process;

FIG. 7 is a view explaining a method of etching a wafer according to the present invention using a continuous process; and

FIGS. 8 and 9 are cross-sectional views showing a bulk silicon solar cell including a wafer substrate according to an embodiment of the present invention.

### DETAILED DESCRIPTION OF THE INVENTION

Hereinafter, preferred embodiments of the present invention will be described in detail with reference to the accompanying drawings.

FIGS. 1 to 3 are process views explaining a principle of a method of performing an asymmetric etching on a wafer according to an embodiment of the present invention.

First, as shown in FIG. 1, two sheets of wafer 100 are overlapped to allow one side of the two wafers 100 to face each other. For convenience of explanation, although a circular wafer 100 is shown in the drawing, the shape of the wafer 100 is not particularly limited thereto but various shapes of wafer 100 may be used. Also, although two sheets of wafer 100 are overlapped, the present invention is not particularly limited thereto but a plurality of wafers may be overlapped with each other. Meanwhile, the two sheets of wafer 100 overlapped with each other may be maintained in an overlapped state, being fixed by a predetermined structure (not shown).

The wafers 100 may be completely overlapped with each other without an interval and may be disposed spaced at a predetermined distance, wherein the distance between the two wafers 100 may be selected properly depending on a desired etching shape, that is, whether only single side of the wafer 100 is etched, whether both sides are etched but are asymmetrically etched, or whether both sides are etched by the same degree. The shape etched according to the distance will be described later in detail. Meanwhile, although the wafers 100 may be overlapped with each other in entirety as shown in the drawing, they may be overlapped in portions, wherein the difference in the overlapped degree may also be selected properly depending on a desired etching shape, that is, whether an asymmetric etching or a symmetric etching is performed on the wafer 100 in entirety, or whether an asymmetric etching or a symmetric etching is performed on the wafer 100 in portions.

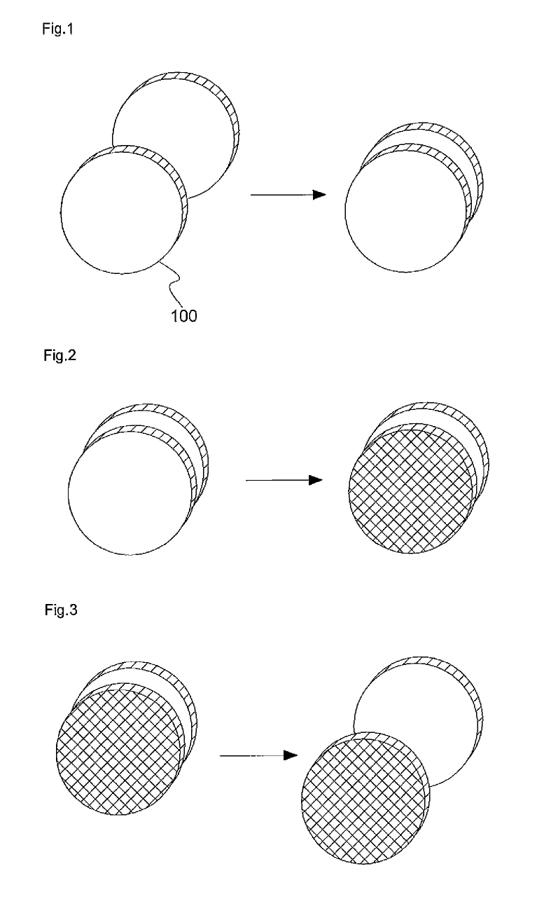

Next, as shown in FIG. 2, an etching is performed on the overlapped wafers 100. The etching may be performed using a well-known etching method using etching solution and may also be performed using a wet etching, a dry etching method, or a combined wet-dry etching, etc. The wet etching is performed in different manners in the case of a single crystal silicon substrate and in the case of a polycrystalline silicon substrate. In the case of the single crystal silicon substrate, a wafer surface etching using basic solution and organic solution may be performed. In the case of the polycrystalline silicon substrate, a wafer surface etching using acid solution and organic solution may be performed. Also, a wafer surface etching by mixing acid solution and basic solution may be performed.

If the wafers are subject to the etching process as described above, the degree of etching is changed according to the degree that the wafers are exposed to the etching solution. It the two wafers 100 are completely overlapped and then are soaked in the etching solution, only one side of the wafer 100 that is exposed to the etching solution is etched, but sides overlapped with each other to face each other are not etched. Meanwhile, the two wafers 100 are spaced at a predetermined distance and then are soaked in the etching solution, such that one side of the wafer 100 that is completely exposed to the etching solution is completely etched, but sides overlapped with each other to face each other are not completely etched. Therefore, the respective wafers 100 can be asymmetrically etched (different shape etching). Meanwhile, if the distance between the two wafers 100 is far enough, both sides of the respective wafers 100 can be symmetrically etched, that is, same shape etching.

When the etching is completed, as shown in FIG. 3, the wafers 100 overlapped with each other are separated.

The respective separated wafers 100 have a single-sided etching structure where only one side is etched or an asymmetric etching structure where both sides are asymmetrically etched, according to the degree that the wafers 100 are overlapped with each other.

Meanwhile, after the plurality of wafers 100 are symmetrically or asymmetrically etched and then separated, an additional etching may further be performed by overlapping or spacing again the plurality of wafers 100 at a predetermined distance. In other words, when the plurality of wafers 100 are etched simultaneously, an etching structure by the desired degree cannot be formed on all of the wafers 100 only through a primary etching so that a secondary etching may be formed additionally by pulling out some wafers 100 or changing the disposition thereof. A simultaneous etching or a different etching can be performed on the plurality of wafers 100 in the manner as described above.

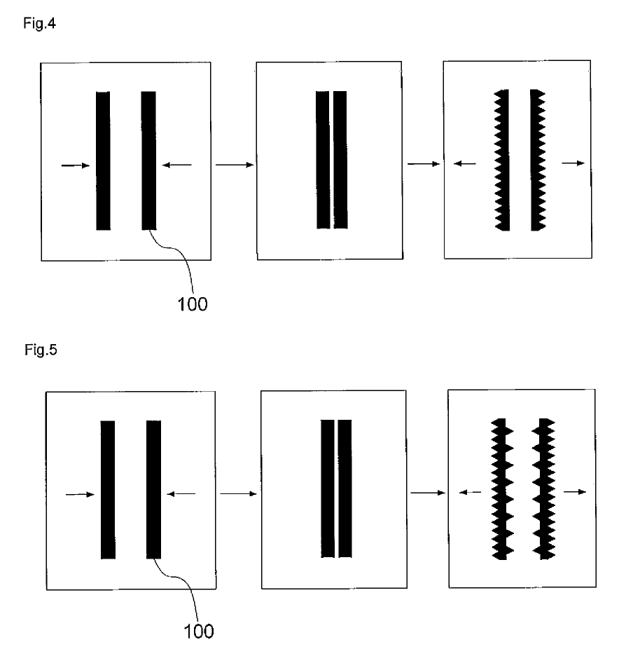

FIG. 4 is a view explaining a method of etching only one side of a wafer 100 according to an embodiment of the present invention.

As shown in FIG. 4, if two wafers 100 are completely overlapped with each other having no distance therebetween and then are etched, the sides where the wafers 100 are overlapped do not contact etching solution so that only one side of the respective wafers 100 is etched.

Therefore, if the overlapped wafers 100 are separated, the wafer 100 that has a single-sided etched structure where only one side thereof is etched is obtained.

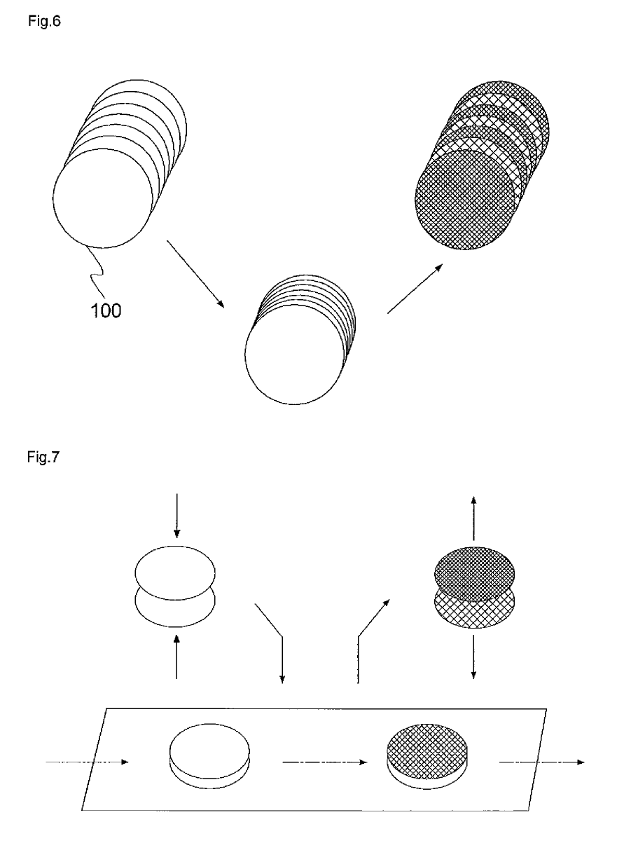

Meanwhile, FIG. 5 is a view explaining a method of etching a wafer 100 asymmetrically according to an embodiment of the present invention.

As shown in FIG. 5, if two wafers 100 are overlapped, being spaced at a predetermined distance, and then are etched, an etching is also performed on the sides that face each other. However, the degree of etching is relatively slight compared to the degree that the side of both sides of the wafer 100, being completely exposed to the etching solution, is etched so that two wafers 100 that are asymmetrically etched are obtained when the two wafers 100 are separated.

As described above, as the two wafers are overlapped with each other and then the etching is performed, the wafer whose only one side is etched or whose both sides are asymmetrically etched can be obtained, thereby making it possible to apply the side etched or the side relatively greatly etched to a solar cell as a light receiving surface.

Also, in the solar cell, when manufacturing a wafer having an uneven structure in order to minimize reflectivity of solar light, the two wafers are overlapped with each other and then are etched, making it possible to obtain two wafers for a solar cell by performing an etching only one time, and an unnecessary etching on a back surface of the wafer can be removed by selectively etching only the light receiving surface, making it possible to reduce work manpower by about half compared to the technique of the related art and to reduce manufacturing costs thereof.

Meanwhile, the single-sided etching or the asymmetric etching as described above may be performed by a discontinuous process or a continuous process.

FIGS. 6 and 7 are views schematically showing a method of performing a single-sided etching or an asymmetric etching on a wafer using a discontinuous process and a continuous process, respectively.

FIGS. 6 and 7 show a method of etching a wafer, comprising: overlapping a plurality of wafers; etching the overlapped wafers; and separating the wafers to obtain wafers having a single-sided etching structure or an asymmetric etching structure, wherein each step is performed discontinuously and continuously.

Referring to FIG. 6, the plurality of wafers to be etched are overlapped with each other having a predetermined gap or having no gap. At this time, the plurality of wafers may be completely overlapped based on a central axis of wafers, but may also be overlapped with each other in portions.

The plurality of wafers overlapped as described above are dipped in the etching solution to allow the sides of the wafers to be textured.

Next, the plurality of wafers are pulled out from the etching solution and then are separated to be dried, thereby completing the process. The plurality of wafers that have undergone the differential etching process as described above have an uneven structure where one side or both sides thereof is/are textured, wherein both sides thereof are asymmetrically etched.

FIG. 7 shows a process where the process of FIG. 6 is performed continuously.

Through an automatic process, the plurality of wafers are overlapped with each other having a predetermined interval or having no interval and then are placed on a moving belt.

Next, after the moving belt moves the plurality of overlapped wafers to a place where an etching process can be performed, the etching process is performed on these wafers.

Next, the plurality of etched wafers are automatically separated and then are dried so that finally, a plurality of wafers whose one side is etched or both sides are asymmetrically etched are produced through one process.

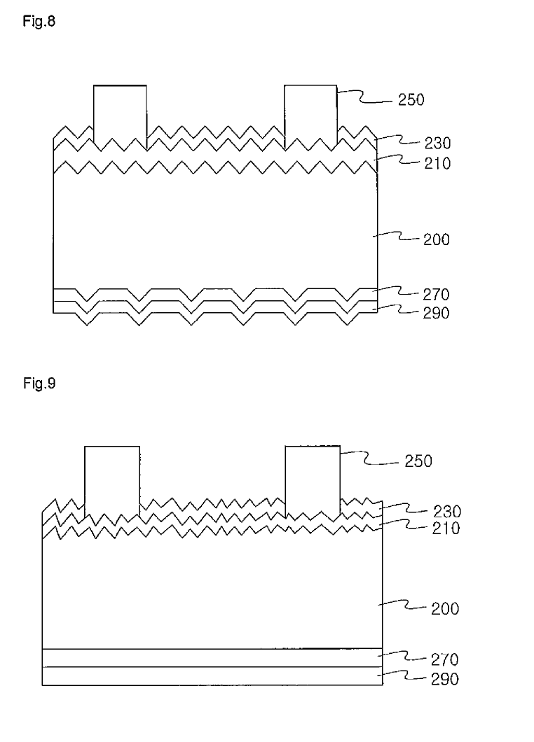

FIGS. 8 and 9 are cross-sectional views showing a bulk silicon solar cell including a wafer substrate according to an embodiment of the present invention.

The bulk silicon solar cell, which is a photovoltaic cell that converts photons into electrical energy using the nature of semiconductors, converts light energy into electrical energy using electrons and holes generated by the absorbed photons. The bulk silicon solar cell may be constituted having various structures.

In particular, in the bulk silicon solar cell shown in FIG. 8, centering on a water substrate 200, an emitter 210 and an anti-reflection layer 230 are provided sequentially on a light receiving surface, and a front surface electrode 250 that connects with the emitter 210 is included. Also, a back surface field layer 270 and a back surface electrode 290 are formed on a non-light receiving surface that is opposite to the light receiving surface.

Referring to FIG. 8, the unevenness on the light receiving surface of the silicon wafer substrate and the unevenness on the non-light receiving surface thereof have a regular pyramid shape, wherein they are different in view of the frequency of unevenness or the density thereof.

In other words, it can be appreciated that in FIG. 8, the density of unevenness on the light receiving surface of the silicon wafer substrate 200 is higher than that on the non-light receiving surface thereof. The both sides of the asymmetric wafer substrates can be implemented through the method of etching the wafer as described above.

Although the uneven shape in FIG. 8 proposes a pyramid shape wherein the convex portions have a regular shape, the present invention is not particularly limited thereto but various shapes thereof may also be applied thereto by those skilled in the art. The pattern of the convex portions of the unevenness may be regular or irregular.

In the bulk silicon solar cell in FIG. 9, centering on a wafer substrate 200, an emitter 210 and an anti-reflection layer 230 are provided sequentially on a light receiving surface formed with irregular unevenness, and a front surface electrode 250 that connects with the emitter 210 is included. Also, a non-light receiving surface that is opposite to the light receiving surface has a flat surface shape with no unevenness, and a back surface field layer 270 and a back surface electrode 290 are formed thereon.

In the same manner as FIG. 8, the bulk silicon solar cell has a structure where, centering on the silicon wafer substrate, the density of unevenness on the light receiving surface is higher than that on the non-light receiving surface.

The irregular shape of unevenness on the light receiving surface is not particularly limited but may be implemented, having various patterns, shapes, frequencies, depths, and sizes, by those skilled in the art.

In particular, a plurality of holes are formed on the surface part of the light receiving surface of the silicon wafer substrate to form concave portions of the unevenness and the portions convex between the holes form to convex portions.

The shape of the hole is not limited but may be variously implemented, such as a multilateral column shape, a circular cylinder shape, a pencil lead shape, a test-tube shape, a water cup shape, a water bottle shape, and a diamond shape, etc. in view of a cross-section thereof.

The distance between the convex portions of the unevenness may be formed from 10 nm to 10 μm, at minimum, and from 10 nm up to 100 μm, at maximum, according to the frequency or density of the unevenness.

The depth between the concave portions of the unevenness is not particularly limited but may be formed variously in the range of 10 nm to 10 μm.

Although the present invention has been described in detail with reference to its presently preferred embodiment, it will be understood by those skilled in the art that various modifications and equivalents can be made without departing from the spirit and scope of the present invention, as set forth in the appended claims. Also, the substances of each constituent explained in the specification can be easily selected and processed by those skilled in the art from the well-known various substances. Also, those skilled in the art can remove a part of the constituents as described in the specification without deterioration of performance or can add constituents for improving the performance. Furthermore, those skilled in the art can change the order to methodic steps explained in the specification according to environments of processes or equipments. Thus, it is intended that the present invention covers the modifications and variations of this invention provided they come within the scope of the appended claims and their equivalents.

What is claimed is:

1. A method of etching a wafer, comprising:
selectively etching only a single side of the wafer; and
asymmetrically etching both sides of the wafer with different etching rates.

2. The method of etching the wafer according to claim 1, wherein the etching only the single side of the wafer comprises:
closely adhering sides of the two wafers that face each other having no gap;
simultaneously etching sides of the closely adhered wafers, exposed to the external; and
separating the closely adhered wafers.

3. The method of etching the wafer according to claim 1, wherein the asymmetrically etching both sides of the wafer comprises:
overlapping a plurality of wafers so as to have predetermined gaps between the respective wafers;
etching the overlapped wafers; and
separating the overlapped wafers.

4. The method of etching the wafer according to claim 3, wherein the gaps between the respective wafers, into which etching solution can be infiltrated, have different widths.

5. The method of etching the wafer according to claim 3, wherein the plurality of wafers are overlapped with each other, having corresponding central lines or having overlapped portions.

6. The method of etching the wafer according to claims 2 or 3, wherein the respective steps are performed continuously or discontinuously.

7. The method of etching the wafer according to claim 1, wherein the etching of the wafer is performed using any one of a wet etching, a dry etching or a combined wet-dry etching.

8. A solar cell which is a bulk silicon solar cell comprising:
a silicon substrate that has a light receiving surface and a non-light receiving surface,
wherein the light receiving surface and the non-light receiving surface have unevenness in different shapes.

9. The solar cell according to claim 8, wherein the unevenness formed on the light receiving surface is different from that on the non-light receiving surface in view of one or more of the number, size, height, and shape thereof.

10. The solar cell according to claim 8, wherein the number of the unevenness formed on the light receiving surface is greater than that formed on the non-light receiving surface.

11. The solar cell according to claim 8, wherein the reflectivity of the light receiving surface is lower than that of the non-light receiving surface.

12. The solar cell according to claim 8, wherein an emitter doped with semiconductor impurities, an anti-reflection layer, and a front surface electrode are formed sequentially on the light receiving surface of the substrate, and a back surface field (BSF) layer and a back surface electrode are formed sequentially on the non-light receiving surface of the substrate.

13. The solar cell according to claim 8, wherein the etching is performed, differing an etching performance time, an etching performance position, or an etching method.

14. A method of manufacturing a bulk silicon solar cell, comprising:
etching only single side of a silicon substrate selectively or etching both sides of the silicon substrate asymmetrically with different etching rates.
